(19) United States
(12) Patent Application Publication
(10) Pub. No.: US 2026/0163552 A1
(43) Pub. Date: Jun. 11, 2026

(54) RESONATOR ELEMENT, RESONATOR, AND OSCILLATOR

(71) Applicant: SEIKO EPSON CORPORATION, Tokyo (JP)

(72) Inventors: Yusuke Yamamoto, Minowa-machi (JP); Ryuta Nishizawa, Nagano-shi (JP)

(21) Appl. No.: 19/179,298

(22) Filed: Apr. 15, 2025

(30) Foreign Application Priority Data
Apr. 17, 2024 (JP) 2024-066612

(51) Int. Cl. H03H 9/19; H03H 9/05

(52) U.S. Cl. CPC H03H 9/19; H03H 9/0538

(57) ABSTRACT

A resonator element includes a quartz crystal substrate having a resonator portion including a resonator region and a support portion having a thickness larger than a thickness of the resonator portion, and an excitation electrode disposed in the resonator region, in which when a surface roughness in the resonator region of the quartz crystal substrate is set to y [nm], and an oscillation frequency is set to x [MHz], y ≤ 11.4 exp (−x/174.8) + 1.8.

The present application is based on, and claims priority from JP Application Serial Number 2024-066612, filed April 17, 2024, the disclosure of which is hereby incorporated by reference herein in its entirety.

### BACKGROUND

### 1. Technical Field

The present disclosure relates to a resonator element, a resonator, and an oscillator.

### 2. Related Art

JP-A-2014-7693 discloses a resonator element including a rectangular resonator portion, a thick portion having an L shape and formed integrally with the resonator portion, and a slit disposed in the thick portion, with an object of realizing a small piezoelectric resonator element having a small CI value and suppressed nearby spurious at a high frequency using a fundamental mode.

Communication devices are required to perform higher-speed and larger-capacity communication, and the demands on the resonator element are also increasing toward high frequencies. On the other hand, as the frequency becomes high, the CI value tends to increase, and there is an increasing number of cases where the required performance of the oscillator cannot be satisfied. Therefore, as in the piezoelectric resonator element of JP-A-2014-7693, there is a limit to realizing a higher frequency or a lower CI value only by devising the disposition of the resonator portion or the thick portion.

### SUMMARY

According to an aspect of the present disclosure, there is provided a resonator element including: a quartz crystal substrate having a resonator portion including a resonator region and a support portion having a thickness larger than a thickness of the resonator portion; and an excitation electrode disposed in the resonator region, in which when a surface roughness in the resonator region of the quartz crystal substrate is set to y [nm], and an oscillation frequency is set to x [MHz], y ≤ 11.4 exp (−x/174.8) + 1.8.

According to another aspect of the present disclosure, there is provided a resonator including: the resonator element and a container configured to accommodate the resonator element.

According to still another aspect of the present disclosure, there is provided an oscillator including: the resonator element; an oscillation circuit configured to excite the resonator element; and a container configured to accommodate the resonator element and the oscillation circuit.

### BRIEF DESCRIPTION OF THE DRAWINGS

FIG. 1 is a perspective view illustrating a configuration of a resonator element according to a first embodiment.

FIG. 2 is a diagram describing a relationship between an AT cut quartz crystal substrate and a crystal axis of quartz crystal.

FIG. 3 is a plan view of the resonator element illustrated in FIG. 1.

FIG. 4 is a cross-sectional view taken along the line IV-IV in FIG. 3.

FIG. 5 is a graph illustrating a relationship between an oscillation frequency and a surface roughness of a resonator region.

FIG. 6 is a plan view illustrating a configuration of a resonator element according to a second embodiment.

FIG. 7 is a cross-sectional view taken along the line VII-VII in FIG. 6.

FIG. 8 is a plan view illustrating a configuration of a resonator element according to a third embodiment.

FIG. 9 is a cross-sectional view taken along the line IX-IX in FIG. 8.

FIG. 10 is a plan view illustrating a configuration of a resonator element according to a fourth embodiment.

FIG. 11 is a cross-sectional view taken along the line XI-XI in FIG. 10.

FIG. 12 is a plan view illustrating a configuration of a resonator element according to a fifth embodiment.

FIG. 13 is a cross-sectional view taken along the line XIII-XIII in FIG. 12.

FIG. 14 is a plan view illustrating a configuration of a resonator element according to a sixth embodiment.

FIG. 15 is a cross-sectional view taken along the line XV-XV in FIG. 14.

FIG. 16 is a plan view illustrating a configuration of a resonator according to a seventh embodiment.

FIG. 17 is a cross-sectional view taken along the line XVII-XVII in FIG. 16.

FIG. 18 is a plan view illustrating a configuration of an oscillator according to an eighth embodiment.

FIG. 19 is a cross-sectional view taken along the line XIX-XIX in FIG. 18.

### DESCRIPTION OF EMBODIMENTS

### 1. First Embodiment

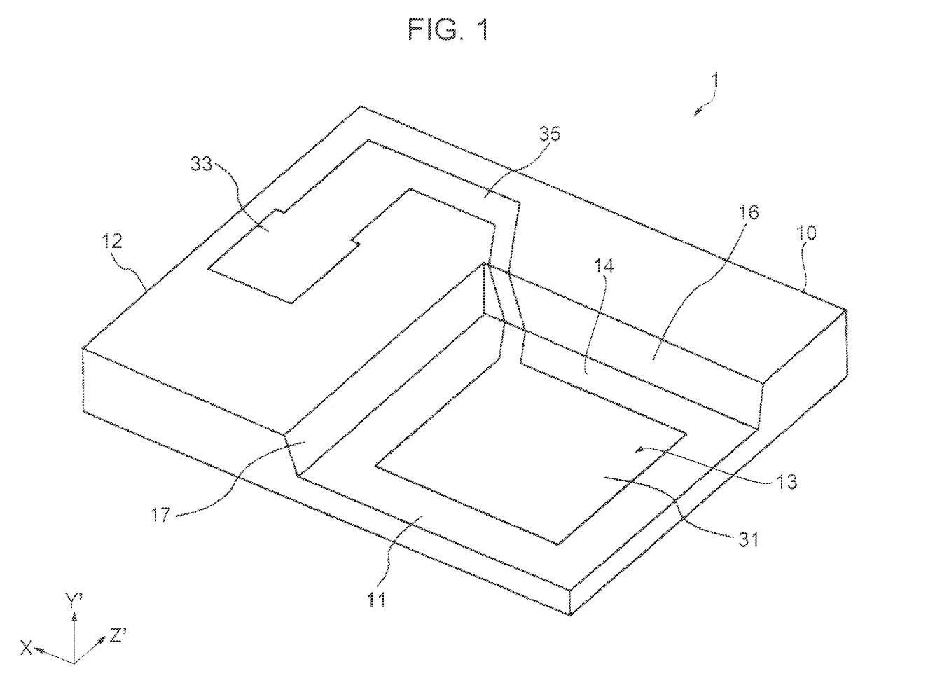

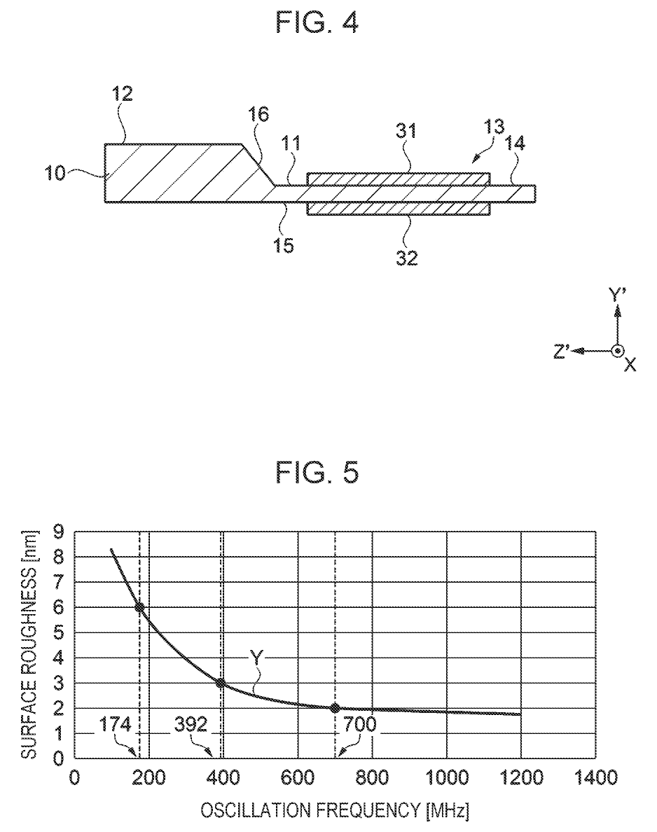

A resonator element 1 according to the first embodiment will be described with reference to FIGS. 1 to 4.

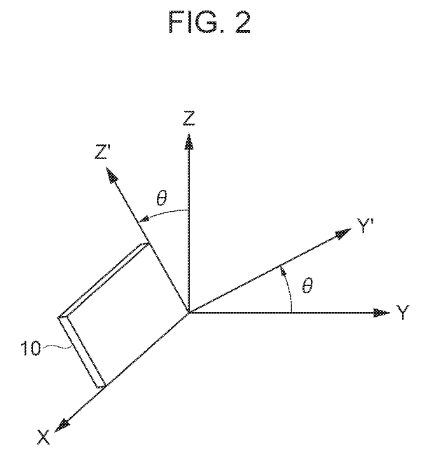

For convenience of description, in each of the following drawings except FIGS. 2, 5, 18, and 19, an X axis, a Y' axis, and a Z' axis are illustrated as three axes orthogonal to each other. In addition, a longitudinal direction of the resonator element 1 is referred to as an "X direction" as a direction along the X axis, a thickness direction of the resonator element 1 is referred to as a "Y' direction" as a direction along the Y' axis, and a direction perpendicular to the X axis and the Y' axis is referred to as a "Z' direction" as a direction along the Z' axis. In addition, an arrow side of each axis is also referred to as a "positive side", and the side opposite to the arrow is also referred to as a "negative side".

As illustrated in FIG. 1, the resonator element 1 of the present embodiment includes a quartz crystal substrate 10 having a resonator portion 11 including a resonator region 13 and a support portion 12 having a thickness larger than that of the resonator portion 11, and excitation electrodes 31 and 32 disposed in the resonator region 13.

The quartz crystal substrate 10 is a plate-shaped substrate. Here, the quartz crystal, which is a material of the quartz crystal substrate 10, belongs to a trigonal crystal system, and has crystal axes X, Y, and Z orthogonal to each other as illustrated in FIG. 2. The X axis, the Y axis, and the Z axis are respectively referred to as an electrical axis, a mechanical axis, and an optical axis. The quartz crystal substrate 10 of the present embodiment is a "rotated Y cut quartz crystal substrate" cut out along a plane obtained by rotating the XZ plane by a predetermined angle θ around the X axis, and for example, the substrate when cut out along a plane obtained by rotating the XZ plane by θ = 35°15' is referred to as an "AT cut quartz crystal substrate". The resonator element 1 having excellent temperature characteristics is obtained by using the quartz crystal substrate 10.

However, the quartz crystal substrate 10 is not limited to the AT cut quartz crystal substrate, as long as the thickness-shear resonance can be excited, and for example, a BT cut quartz crystal substrate may be used.

In the following, the Y axis and the Z axis rotated around the X axis corresponding to the angle θ are referred to as a Y' axis and a Z' axis. That is, the quartz crystal substrate 10 has a thickness in the Y' direction and extends in an XZ' plane direction.

The quartz crystal substrate 10 has an elongated shape in which the X direction is a long side and the Z' direction is a short side in a plan view. In addition, the quartz crystal substrate 10 has a negative X direction as a tip end side and a positive X direction as a base end side.

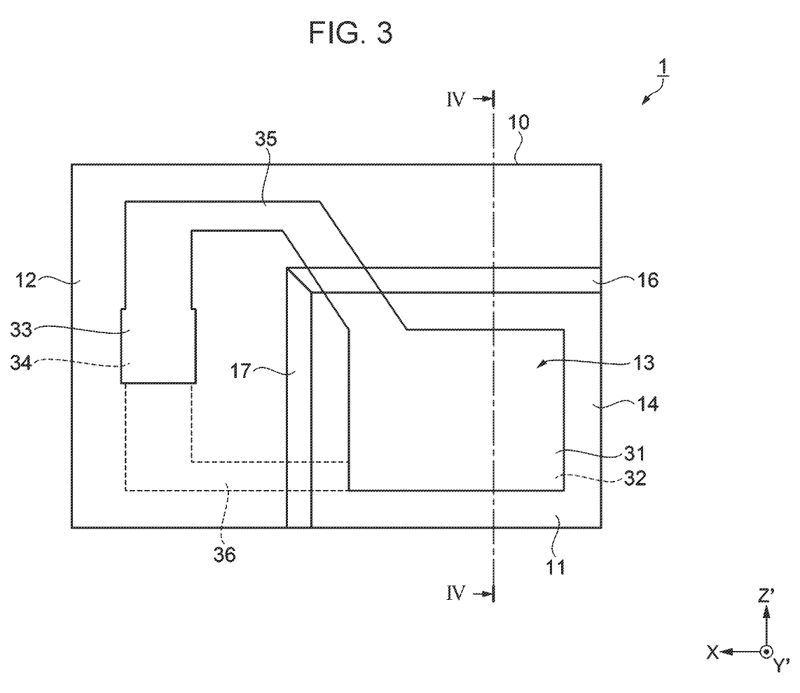

As illustrated in FIGS. 1 and 3, the quartz crystal substrate 10 includes the resonator portion 11 including a resonator region 13 which is a region where resonance energy is confined, and the support portion 12 which is integrated with the resonator portion 11 and has a thickness larger than that of the resonator portion 11.

The resonator portion 11 is biased to the X direction negative side and the Z' direction negative side with respect to the center of the quartz crystal substrate 10, and a part of its outer edge is exposed from the support portion 12. That is, a part of the outer edge of the resonator portion 11 forms a part of the outer edge of the quartz crystal substrate 10. In a plan view of the resonator element 1, it is preferable that an area of the resonator portion 11 is equal to or smaller than half an area of the quartz crystal substrate 10. As a result, the support portion 12 having a high mechanical strength can be formed sufficiently wide, and thus the rigidity of the resonator portion 11 can be sufficiently ensured.

The support portion 12 protrudes from the resonator portion 11 on one surface 14 side of the resonator portion 11. Specifically, as illustrated in FIGS. 1, 3, and 4, a main surface of the support portion 12 on the Y' direction positive side is provided to protrude to the Y' direction positive side from one surface 14 which is the main surface of the resonator portion 11 on the Y' direction positive side. On the other hand, the main surface of the support portion 12 on the Y' direction negative side is provided on the same plane as the other surface 15 which is the main surface of the resonator portion 11 on the Y' direction negative side.

The support portion 12 has a support portion 12 coupled to the outer edge of the resonator portion 11 on the X direction positive side and a support portion 12 coupled to the outer edge of the resonator portion 11 on the Z' direction positive side. Therefore, the support portion 12 has a structure that is bent along the resonator portion 11 in a plan view, and has a substantially L shape. Therefore, the mass of the resonator element 1 on the tip end side can be reduced while maintaining the rigidity of the resonator portion 11 of the resonator element 1. In addition, the size of the resonator element 1 can be reduced.

The support portion 12 includes a coupling portion 16 that is continuously provided on the outer edge of the resonator portion 11 on the Z' direction positive side to couple the support portion 12 and the resonator portion 11 and that has an inclined portion of which a thickness gradually increases toward the positive Z' direction, and a coupling portion 17 that is continuously provided on an outer edge of the resonator portion 11 on the X direction positive side and that has an inclined portion of which a thickness gradually increases toward the positive X direction. In addition, the support portion 12 on the coupling portion 17 side is a mounting portion and is fixed to a container or the like using a conductive adhesive or the like.

The quartz crystal substrate 10 is formed with a pair of excitation electrodes 31 and 32, a pair of pad electrodes 33 and 34, and a pair of lead electrodes 35 and 36.

The excitation electrodes 31 and 32 are disposed in the resonator region 13 of the resonator portion 11. The excitation electrode 31 is disposed on one surface 14 of the resonator portion 11. On the other hand, the excitation electrode 32 is disposed to face the excitation electrode 31 on the other surface 15 of the resonator portion 11. Each of the excitation electrodes 31 and 32 is a substantially rectangular shape in which the X direction is the long side and the Z' direction is the short side.

The pad electrodes 33 and 34 are disposed at a base portion of the support portion 12 on the coupling portion 17 side. The pad electrode 33 is disposed on one surface 14 side of the resonator portion 11. On the other hand, the pad electrode 34 is disposed on the other surface 15 side of the resonator portion 11 to face the pad electrode 33.

The lead electrodes 35 and 36 are disposed on the resonator portion 11 and the support portion 12. The lead electrode 35 electrically couples the excitation electrode 31 and the pad electrode 33. On the other hand, the lead electrode 36 electrically couples the excitation electrode 32 and the pad electrode 34. The lead electrodes 35 and 36 are disposed not to overlap with each other via the quartz crystal substrate 10. As a result, the electrostatic capacitance between the lead electrodes 35 and 36 can be suppressed.

Next, in order to realize higher frequency and lower CI value, the relationship between the oscillation frequency of the resonator element 1 and the surface roughness of the resonator region 13 will be described with reference to FIG. 5.

FIG. 5 is a graph in which the surface roughness of the resonator region 13 in which the CI value with respect to the oscillation frequency of the resonator element 1 satisfies a specified value is measured and plotted, and is a graph illustrating an approximation curve Y calculated by the least squares method from three plots.

The approximation curve Y satisfies a relationship of y ≤ 11.4 exp (−x/174.8) + 1.8 when the surface roughness in the resonator region 13 of the quartz crystal substrate 10 is set to y [nm] and the oscillation frequency is set to x [MHz]. The surface roughness in the resonator region 13 of the quartz crystal substrate 10 is the root mean square height measured by a white light interferometer.

From FIG. 5, the resonator element 1 having a low CI value can be obtained by setting the surface roughness in the resonator region 13 to the value of the approximation curve Y at each oscillation frequency.

In addition, when the surface roughness in the resonator region 13 is 6 nm or less, the resonator element 1 having a low CI value can be obtained at an oscillation frequency of 174 MHz or less.

In addition, when the surface roughness in the resonator region 13 is set to 3 nm or less, the resonator element 1 having a low CI value can be obtained at an oscillation frequency of 392 MHz or less.

In addition, when the surface roughness in the resonator region 13 is 2 nm or less, the resonator element 1 having a low CI value can be obtained at an oscillation frequency of 700 MHz or less.

That is, the resonator element 1 having a low CI value can be obtained by setting the surface roughness in the resonator region 13 to the value of the approximation curve Y or less at each oscillation frequency.

As described above, the resonator element 1 of the present embodiment satisfies the relationship of y ≤ 11.4 exp (−x/174.8) + 1.8 when the surface roughness in the resonator region 13 of the quartz crystal substrate 10 is set to y [nm] and the oscillation frequency is set to x [MHz], and thus a low CI value can be obtained even in a high frequency. Therefore, the required performance of the oscillator used in communication devices for high-speed, large-capacity communication can be satisfied.

### 2. Second Embodiment

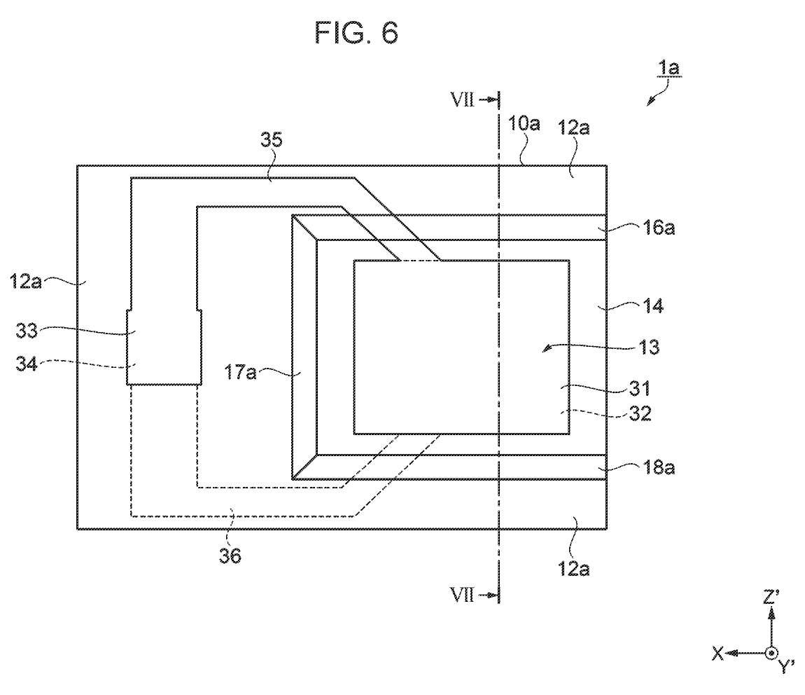

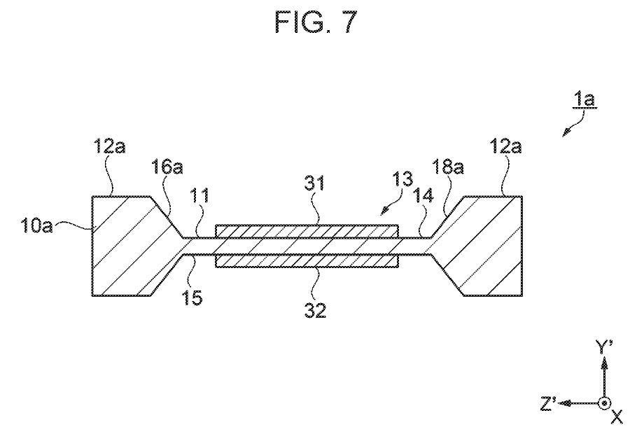

Next, a resonator element 1a according to the second embodiment will be described with reference to FIGS. 6 and 7.

The resonator element 1a of the present embodiment is the same as the resonator element 1 of the first embodiment except that the structure of a quartz crystal substrate 10a is different from that of the resonator element 1 of the first embodiment. The following description will focus on the differences from the above-described first embodiment, and the description of the same matters will be omitted by assigning the same reference numerals.

As illustrated in FIGS. 6 and 7, the resonator element 1a includes a quartz crystal substrate 10a having a resonator portion 11 including a resonator region 13 and a support portion 12a having a thickness larger than that of the resonator portion 11, and excitation electrodes 31 and 32 disposed in the resonator region 13.

The support portion 12a protrudes from the resonator portion 11 on one surface 14 side of the resonator portion 11, and also protrudes from the resonator portion 11 on the other surface 15 side, which is a back side of the one surface 14. That is, since the resonator portion 11 is formed by etching the resonator portion 11 from both the one surface 14 and the other surface 15, the etching amount on one surface can be reduced, and the resonator element 1a having a small variation in plate thickness of the resonator portion 11 can be obtained.

The support portion 12a includes a coupling portion 16a that is continuously provided on the outer edge of the resonator portion 11 on the Z' direction positive side to couple the support portion 12a and the resonator portion 11 and that has an inclined portion of which a thickness gradually increases toward the positive Z' direction, a coupling portion 17a that is continuously provided on an outer edge of the resonator portion 11 on the X direction positive side and that has an inclined portion of which a thickness t gradually increases toward the positive X direction, and a coupling portion 18a that is continuously provided on the outer edge of the resonator portion 11 on the Z' direction negative side and that has an inclined portion of which a thickness gradually increases toward the negative Z' direction.

The resonator portion 11 is coupled to the support portion 12a at the outer edge on the X direction positive side, the outer edge on the Z' direction positive side, and the outer edge on the Z' direction negative side, and an outer edge on the X direction negative side that is a part of the outer edge of the resonator portion 11 forms a part of the outer edge of the quartz crystal substrate 10a. Therefore, the rigidity of the resonator portion 11 of the resonator element 1a is further improved.

In the present embodiment, the support portion 12a is coupled to the three outer edges of the resonator portion 11, but similar to the first embodiment, the support portion 12a may be coupled to the two outer edges of the resonator portion 11.

With such a configuration, the resonator element 1a has a low CI value at a high frequency, the plate thickness variation of the resonator portion 11 can be reduced, and the resonator element 1a with further improved rigidity of the resonator portion 11 can be obtained.

### 3. Third Embodiment

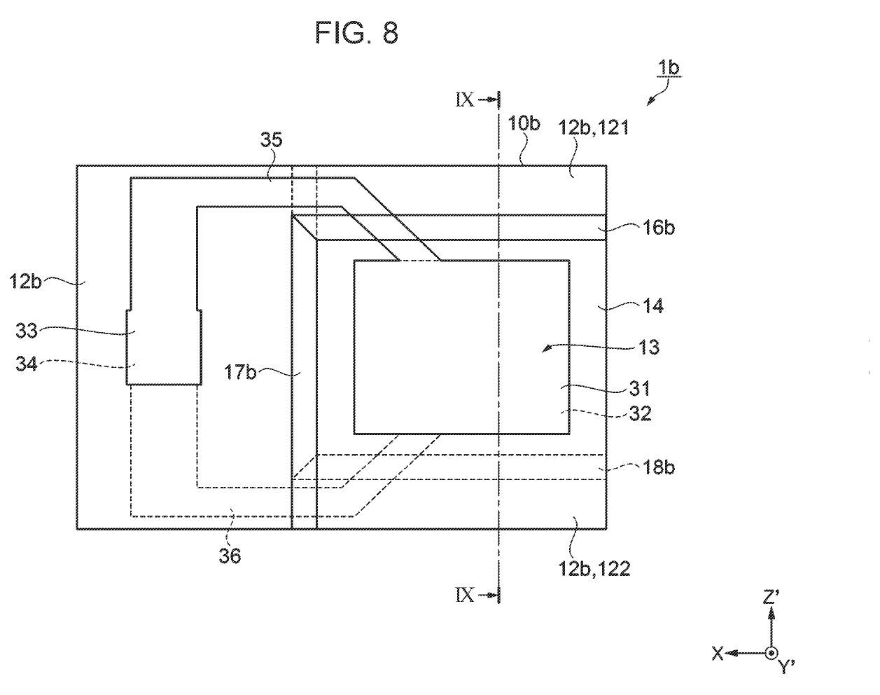

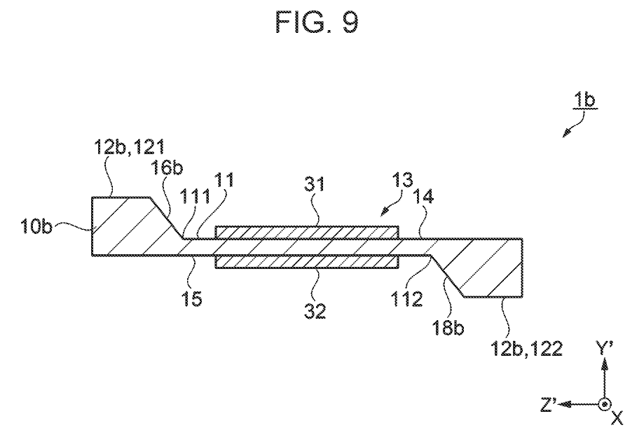

Next, a resonator element 1b according to the third embodiment will be described with reference to FIGS. 8 and 9.

The resonator element 1b of the present embodiment is the same as the resonator element 1 of the first embodiment except that the structure of a quartz crystal substrate 10b is different from that of the resonator element 1 of the first embodiment. The following description will focus on the differences from the above-described first embodiment, and the description of the same matters will be omitted by assigning the same reference numerals.

As illustrated in FIGS. 8 and 9, the resonator element 1b includes a quartz crystal substrate 10b having a resonator portion 11 including a resonator region 13 and a support portion 12b having a thickness larger than that of the resonator portion 11, and excitation electrodes 31 and 32 disposed in the resonator region 13.

The support portion 12b includes a first support portion 121 disposed along the outer edge on the positive Z' side, which is one outer edge of the resonator portion 11, and a second support portion 122 disposed along the outer edge on the negative Z' side, which is the other outer edge on the opposite side to one outer edge of the resonator portion 11. The first support portion 121 protrudes from the resonator portion 11 on one surface 14 side of the resonator portion 11, and the second support portion 122 protrudes from the resonator portion 11 on the other surface 15 side on the back side of the one surface 14. That is, since the resonator portion 11 is formed by etching it from both surfaces, the etching amount on one surface can be reduced, and the resonator element 1b having a small variation in plate thickness of the resonator portion 11 can be obtained.

The first support portion 121 and the resonator portion 11 are coupled to each other by a coupling portion 16b that is continuously provided on an outer edge 111 of the resonator portion 11 on the Z' direction positive side and that has an inclined portion of which the thickness gradually increases toward the positive Z' direction. In addition, the support portion 12b and the resonator portion 11 are coupled to each other by a coupling portion 17b that is continuously provided on the outer edge of the resonator portion 11 on the X direction positive side and that has an inclined portion of which the thickness gradually increases toward the positive X direction. The second support portion 122 and the resonator portion 11 are coupled to each other by a coupling portion 18b that is continuously provided on an outer edge 112 of the resonator portion 11 on the Z' direction negative side and that has an inclined portion where the thickness gradually increases toward the negative Z' direction. Therefore, the resonator region 13 of the resonator portion 11 can be widened.

In the resonator portion 11, only the outer edge on the X direction negative side, which is a part of the outer edge of the resonator portion 11, forms a part of the outer edge of the quartz crystal substrate 10b. Therefore, the rigidity of the resonator portion 11 of the resonator element 1b is further improved.

With such a configuration, the resonator element 1b has a low CI value at a high frequency, the plate thickness variation of the resonator portion 11 can be reduced, the resonator region 13 of the resonator portion 11 can be widened, and the resonator element 1b with further improved rigidity of the resonator portion 11 can be obtained.

### 4. Fourth Embodiment

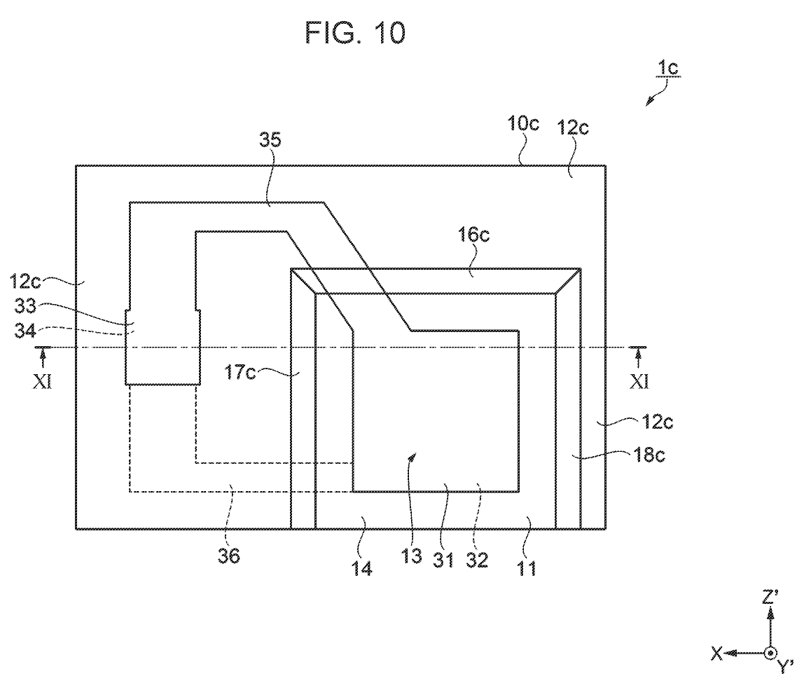

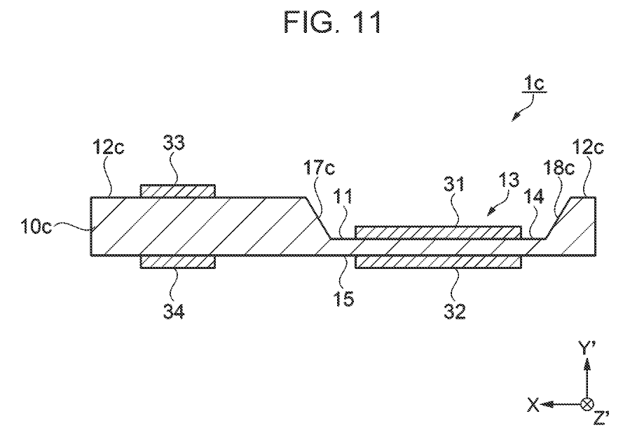

Next, a resonator element 1c according to the fourth embodiment will be described with reference to FIGS. 10 and 11.

The resonator element 1c of the present embodiment is the same as the resonator element 1 of the first embodiment except that the structure of a quartz crystal substrate 10c is different from that of the resonator element 1 of the first embodiment. The following description will focus on the differences from the above-described first embodiment, and the description of the same matters will be omitted by assigning the same reference numerals.

As illustrated in FIGS. 10 and 11, the resonator element 1c includes a quartz crystal substrate 10c having a resonator portion 11 including a resonator region 13 and a support portion 12c having a thickness larger than that of the resonator portion 11, and excitation electrodes 31 and 32 disposed in the resonator region 13.

The support portion 12c protrudes from the resonator portion 11 on one surface 14 side of the resonator portion 11.

In addition, the support portion 12c includes a coupling portion 16c that is continuously provided on the outer edge of the resonator portion 11 on the Z' direction positive side to couple the support portion 12c and the resonator portion 11 and that has an inclined portion of which a thickness gradually increases toward the positive Z' direction, a coupling portion 17c that is continuously provided on an outer edge of the resonator portion 11 on the X direction positive side and that has an inclined portion of which a thickness t gradually increases toward the positive X direction, and a coupling portion 18c that is continuously provided on the outer edge of the resonator portion 11 on the X direction negative side and that has an inclined portion of which a thickness gradually increases toward the negative X direction.

The resonator portion 11 is coupled to the support portion 12c at the outer edge on the Z' direction positive side, the outer edge on the X direction positive side, and the outer edge on the X direction negative side, and an outer edge on the Z' direction negative side that is a part of the outer edge of the resonator portion 11 forms a part of the outer edge of the quartz crystal substrate 10c. Therefore, the rigidity of the resonator portion 11 of the resonator element 1c is further improved.

In the present embodiment, the resonator portion 11 is formed by etching it from one surface 14 side, but the resonator portion 11 may be formed by etching it from the other surface 15 side as well at the same time as in the second embodiment and the third embodiment.

With such a configuration, the resonator element 1c has a low CI value at a high frequency, and the resonator element 1c with further improved rigidity of the resonator portion 11 can be obtained.

### 5. Fifth Embodiment

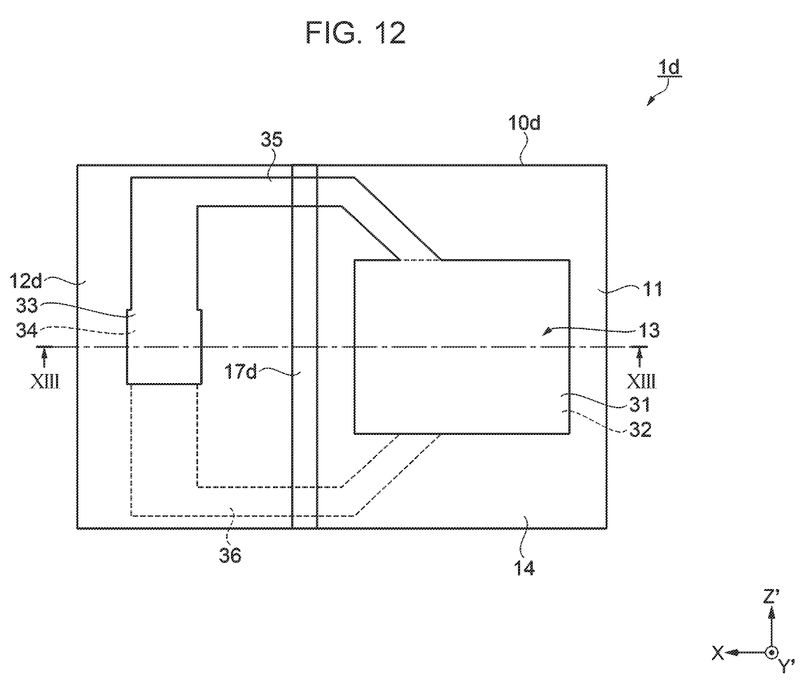

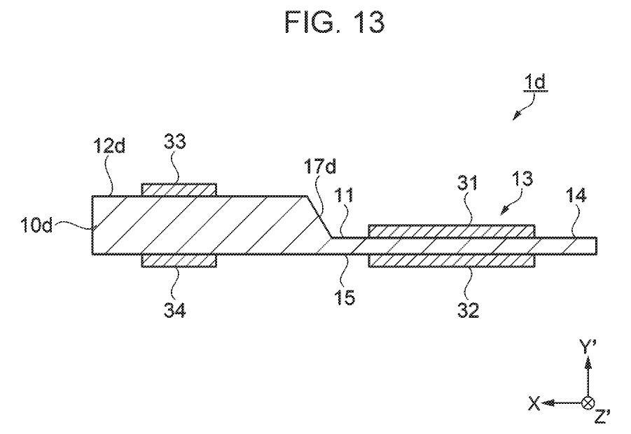

Next, a resonator element 1d according to a fifth embodiment will be described with reference to FIGS. 12 and 13.

The resonator element 1d of the present embodiment is the same as the resonator element 1 of the first embodiment except that the structure of a quartz crystal substrate 10d is different from that of the resonator element 1 of the first embodiment. The following description will focus on the differences from the above-described first embodiment, and the description of the same matters will be omitted by assigning the same reference numerals.

As illustrated in FIGS. 12 and 13, the resonator element 1d includes a quartz crystal substrate 10d having a resonator portion 11 including a resonator region 13 and a support portion 12d having a thickness larger than that of the resonator portion 11, and excitation electrodes 31 and 32 disposed in the resonator region 13.

The support portion 12d protrudes from the resonator portion 11 on one surface 14 side of the resonator portion 11.

In addition, the support portion 12d includes a coupling portion 17d that is continuously provided on an outer edge of the resonator portion 11 on the X direction positive side to couple the support portion 12d and the resonator portion 11, and has an inclined portion of which the thickness gradually increases toward the positive X direction.

The resonator portion 11 is coupled to the support portion 12d at the outer edge on the X direction positive side, and the outer edge on the Z' direction positive side, the outer edge on the X direction negative side, and the outer edge on the Z' direction negative side, which are part of the outer edge of the resonator portion 11, form a part of the outer edge of the quartz crystal substrate 10d. Therefore, the resonator region 13 of the resonator portion 11 can be widened.

In the present embodiment, the resonator portion 11 is formed by etching it from one surface 14 side, but the resonator portion 11 may be formed by etching it from the other surface 15 side as well at the same time as in the second embodiment and the third embodiment.

With such a configuration, the resonator element 1d has a low CI value at a high frequency, and the resonator element 1d with a wide resonator region 13 of the resonator portion 11 can be obtained.

### 6. Sixth Embodiment

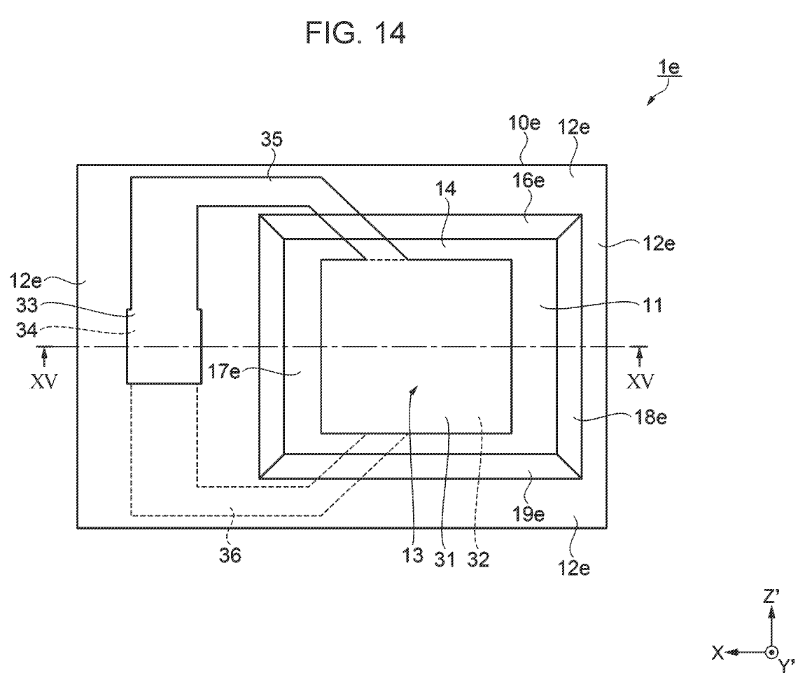

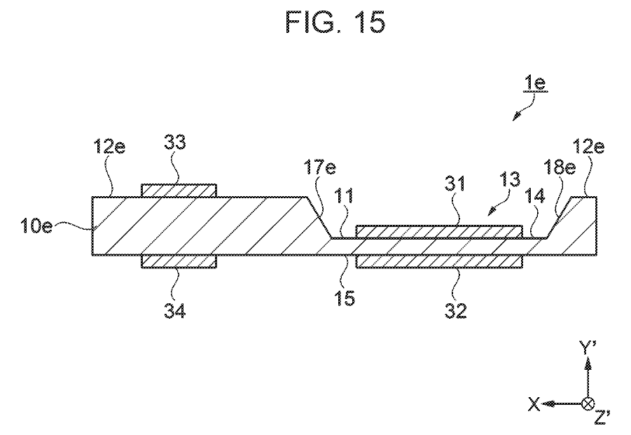

Next, a resonator element 1e according to the sixth embodiment will be described with reference to FIGS. 14 and 15.

The resonator element 1e of the present embodiment is the same as the resonator element 1 of the first embodiment except that the structure of a quartz crystal substrate 10e is different from that of the resonator element 1 of the first embodiment. The following description will focus on the differences from the above-described first embodiment, and the description of the same matters will be omitted by assigning the same reference numerals.

As illustrated in FIGS. 14 and 15, the resonator element 1e includes a quartz crystal substrate 10e having a resonator portion 11 including a resonator region 13 and a support portion 12e having a thickness larger than that of the resonator portion 11, and excitation electrodes 31 and 32 disposed in the resonator region 13.

The support portion 12e protrudes from the resonator portion 11 on one surface 14 side of the resonator portion 11.

In addition, the support portion 12e surrounds the resonator portion 11 in a plan view. That is, the support portion 12e includes a coupling portion 16e that is continuously provided on the outer edge of the resonator portion 11 on the Z' direction positive side to couple the support portion 12e and the resonator portion 11 and that has an inclined portion of which a thickness gradually increases toward the positive Z' direction, a coupling portion 17e that is continuously provided on an outer edge of the resonator portion 11 on the X direction positive side and that has an inclined portion of which a thickness t gradually increases toward the positive X direction, a coupling portion 18e that is continuously provided on the outer edge of the resonator portion 11 on the X direction negative side and that has an inclined portion of which a thickness gradually increases toward the negative X direction, and a coupling portion 19e that is continuously provided on the outer edge of the resonator portion 11 on the Z' direction negative side and that has an inclined portion of which a thickness gradually increases toward the negative Z' direction. Therefore, the rigidity of the resonator portion 11 of the resonator element 1e is further improved.

In the present embodiment, the resonator portion 11 is formed by etching it from one surface 14 side, but the resonator portion 11 may be formed by etching it from the other surface 15 side as well at the same time as in the second embodiment and the third embodiment.

With such a configuration, the resonator element 1e has a low CI value at a high frequency, and the resonator element 1e with further improved rigidity of the resonator portion 11 can be obtained.

### 7. Seventh Embodiment

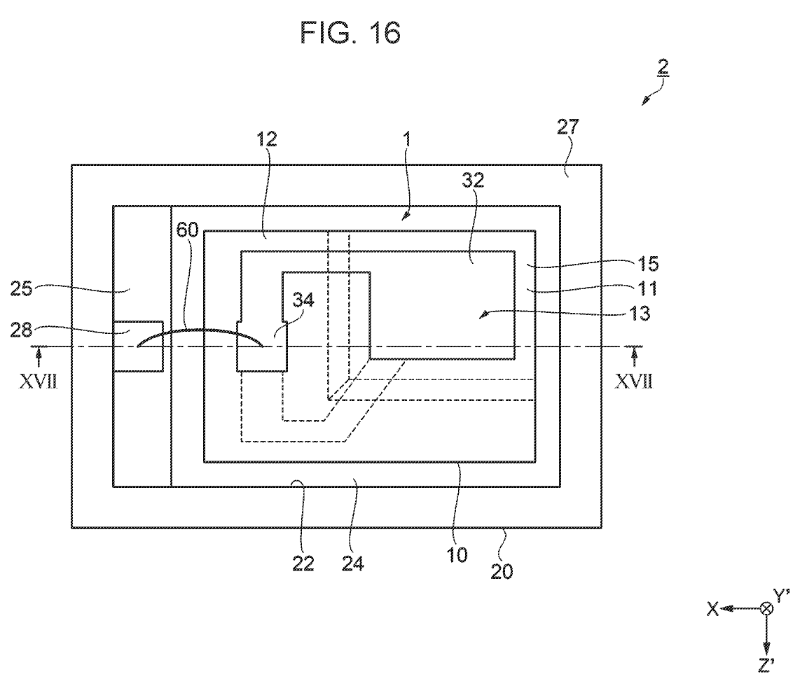

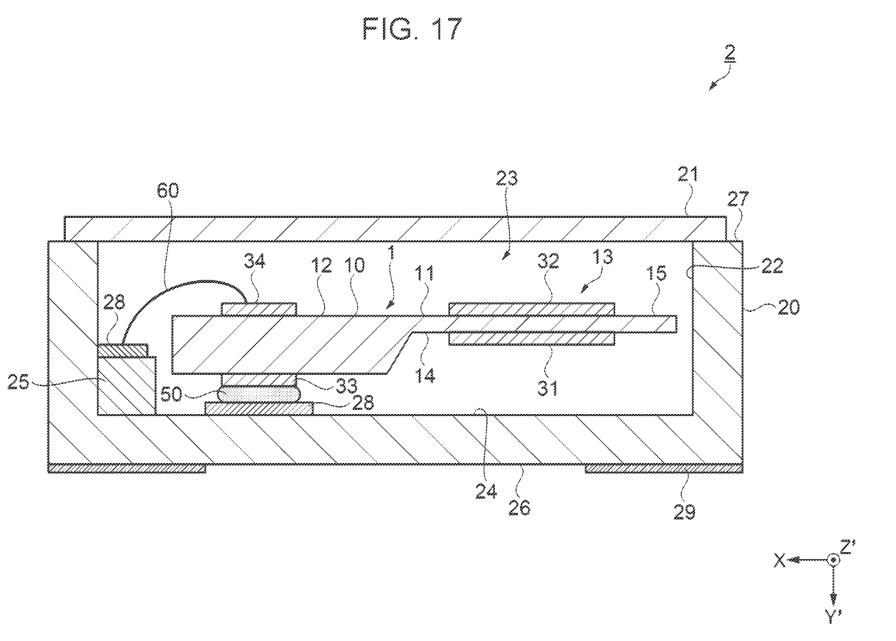

Next, a resonator 2 according to the seventh embodiment will be described with reference to FIGS. 16 and 17. In the present description, the resonator 2 including the resonator element 1 described above will be described as an example. In addition, in FIG. 16, for convenience of description of an internal configuration of the resonator 2, a state in which a lid 21 is removed is illustrated.

As illustrated in FIGS. 16 and 17, the resonator 2 includes the resonator element 1, a container 20 that accommodates the resonator element 1, and the lid 21 that forms an accommodation space 23 together with the container 20.

The container 20 has a recess portion 22 that is open to the lid 21 side, and the lid 21 that closes the opening of the recess portion 22 is bonded to an upper surface 27. By closing the recess portion 22 of the container 20 with the lid 21, the accommodation space 23 that accommodates the resonator element 1 is formed. The accommodation space 23 may be in a reduced pressure or vacuum state, or may be sealed with an inert gas such as nitrogen (Ni), helium (He), or argon (Ar).

The constituent material of the container 20 is not particularly limited, but various ceramics such as aluminum oxide can be used. In addition, the constituent material of the lid 21 is not particularly limited, but may be a member whose linear expansion coefficient is close to that of the constituent material of the container 20. The bonding of the container 20 and the lid 21 is not particularly limited, and may be bonded via an adhesive or may be bonded by seam welding or the like.

An internal terminal 28 is formed at an inner bottom surface 24 of the container 20, and the internal terminal 28 is formed at a pedestal portion 25 protruding from the inner bottom surface 24 toward the lid 21 side. In addition, a plurality of external terminals 29 are formed at a lower surface 26 of the container 20. The internal terminal 28 on the inner bottom surface 24 is electrically coupled to the external terminal 29 via a through electrode (not illustrated) formed in the container 20, and the internal terminal 28 on the pedestal portion 25 is electrically coupled to the external terminal 29 via a through electrode (not illustrated) formed in the container 20.

The resonator element 1 accommodated in the accommodation space 23 is fixed to the container 20 by a bonding member 50 which is a conductive adhesive, in the support portion 12, with one surface 14 of the resonator portion 11 facing the inner bottom surface 24 of the container 20. The bonding member 50 is provided in contact with the internal terminal 28 and the pad electrode 33. As a result, the internal terminal 28 and the pad electrode 33 are electrically coupled to each other via the bonding member 50. By supporting the resonator element 1 at one place or one point using the bonding member 50, for example, the stress generated in the resonator element 1 due to the difference in the coefficient of thermal expansion between the container 20 and the quartz crystal substrate 10 can be suppressed.

The pad electrode 34 of the resonator element 1 is electrically coupled to the internal terminal 28 via a bonding wire 60. As described above, since the pad electrode 34 is disposed to face the pad electrode 33, the pad electrode 34 is positioned directly above the bonding member 50 in a state where the resonator element 1 is fixed to the container 20. Therefore, leakage of the ultrasonic resonance applied to the pad electrode 34 during the wire bonding can be suppressed, and the bonding wire 60 can be more reliably coupled to the pad electrode 34.

With such a configuration, the resonator 2 includes the resonator element 1 having a low CI value at a high frequency, and thus the resonator 2 having a low CI value at a high frequency can be obtained.

In the seventh embodiment, as the constituent materials of the container 20 and the lid 21, various ceramics are described, but the present disclosure is not limited thereto, and a semiconductor substrate may be used.

### 8. Eighth Embodiment

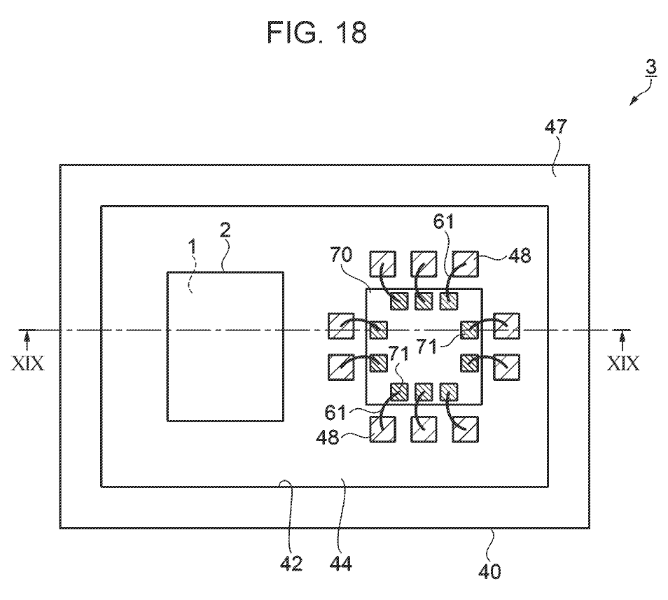

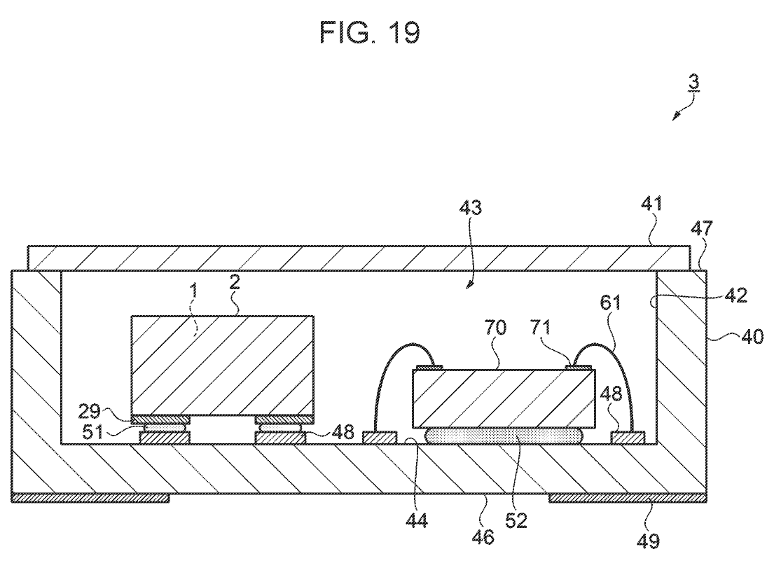

Next, an oscillator 3 according to the eighth embodiment will be described with reference to FIGS. 18 and 19. In the present description, the oscillator 3 including the resonator 2 including the resonator element 1 described above will be described as an example. In addition, in FIG. 18, for convenience of description of an internal configuration of the oscillator 3, a state in which a lid 41 is removed is illustrated. In addition, in FIG. 19, the cross-sectional structure of the resonator 2 is described in FIG. 17 described above, and thus is not illustrated.

As illustrated in FIGS. 18 and 19, the oscillator 3 includes the resonator 2 including the resonator element 1, an oscillation circuit 70 that excites the resonator element 1, a container 40 that accommodates the resonator 2 and the oscillation circuit 70, and the lid 41 that forms an accommodation space 43 together with the container 40.

The container 40 has a recess portion 42 that is open to the lid 41 side, and the lid 41 that closes the opening of the recess portion 42 is bonded to an upper surface 47. By closing the recess portion 42 of the container 40 with the lid 41, the accommodation space 43 that accommodates the resonator 2 and the oscillation circuit 70 is formed.

The constituent material of the container 40 is not particularly limited, but various ceramics such as aluminum oxide can be used. In addition, the constituent material of the lid 41 is not particularly limited. The bonding of the container 40 and the lid 41 is not particularly limited, and may be bonded via an adhesive or may be bonded by seam welding or the like.

A plurality of internal terminals 48 are formed at an inner bottom surface 44 of the container 40. In addition, a plurality of external terminals 49 are formed at a lower surface 46 of the container 40. In the internal terminal 48 on the inner bottom surface 44, the internal terminal 48 disposed in the vicinity of the oscillation circuit 70 in a plan view is electrically coupled to the external terminal 49 via a wiring or a through electrode (not illustrated) formed in the container 40. In addition, the internal terminal 48 disposed at a position overlapping with the resonator 2 in a plan view is electrically coupled to the internal terminal 48 disposed in the vicinity of the oscillation circuit 70 via a wiring (not illustrated).

The resonator 2 accommodated in the accommodation space 43 is fixed to the container 40 by a bonding member 51 such as a conductive adhesive or solder at the external terminal 29. The external terminal 29 and the internal terminal 48 are electrically coupled to each other via the bonding member 51.

The oscillation circuit 70 accommodated in the accommodation space 43 is fixed to the container 40 by a bonding member 52 such as an adhesive. A plurality of circuit terminals 71 are provided on the surface of the oscillation circuit 70 on the lid 41 side, and the circuit terminal 71 is electrically coupled to the internal terminal 48 disposed in the vicinity of the oscillation circuit 70 via a bonding wire 61. Since some of the circuit terminals 71 are electrically coupled to the external terminal 29 of the resonator 2 via the internal terminal 48, the resonator element 1 can be excited. In addition, some of the circuit terminals 71 are electrically coupled to the external terminal 49 via the internal terminal 48, so that power can be input from the external terminal 49, and the oscillation frequency output from the oscillation circuit 70 can be output from the external terminal 49.

With such a configuration, the oscillator 3 includes the resonator element 1 having a low CI value at a high frequency, and thus the oscillator 3 having excellent oscillation characteristics at a high frequency can be obtained.

In the eighth embodiment, the resonator 2 accommodating the resonator element 1 in the container 20 is fixed to the container 40, but a structure in which the resonator element 1 itself is attached to the container 40 may be used. In addition, although not illustrated, a semiconductor substrate at which the oscillation circuit 70 is formed can be used as the container 40. By mounting the resonator element 1 on the semiconductor substrate, a space for the oscillation circuit 70 in the accommodation space 43 is not necessary, and the size of the oscillator 3 can be reduced.

What is claimed is:

1. A resonator element comprising:
a quartz crystal substrate having a resonator portion including a resonator region and a support portion having a thickness larger than a thickness of the resonator portion; and
an excitation electrode disposed in the resonator region, wherein
when a surface roughness in the resonator region of the quartz crystal substrate is set to y [nm], and
an oscillation frequency is set to x [MHz],
11-174y ≤ 11.4 exp (−x/174.8) + 1.8.

2. The resonator element according to claim 1, wherein
the surface roughness is 6 nm or less, and the oscillation frequency is 174 MHz or less.

3. The resonator element according to claim 1, wherein
the surface roughness is 3 nm or less, and the oscillation frequency is 392 MHz or less.

4. The resonator element according to claim 1, wherein
the surface roughness is 2 nm or less, and the oscillation frequency is 700 MHz or less.

5. The resonator element according to claim 1, wherein
the support portion protrudes from the resonator portion on a side of one surface of the resonator portion.

6. The resonator element according to claim 5, wherein
the support portion also protrudes from the resonator portion on a side of another surface, which is a back side of the one surface.

7. The resonator element according to claim 1, wherein
the support portion includes
a first support portion disposed along one outer edge of the resonator portion, and
a second support portion disposed along another outer edge opposite to one outer edge of the resonator portion,
the first support portion protrudes from the resonator portion on a side of one surface of the resonator portion, and
the second support portion protrudes from the resonator portion on a side of another surface on a back side of the one surface.

8. The resonator element according to claim 1, wherein
a part of an outer edge of the resonator portion forms a part of an outer edge of the quartz crystal substrate.

9. The resonator element according to claim 1, wherein
the support portion surrounds the resonator portion in a plan view.

10. A resonator comprising:
the resonator element according to claim 1; and
a container configured to accommodate the resonator element.

11. An oscillator comprising:
the resonator element according to claim 1;
an oscillation circuit configured to excite the resonator element; and
a container configured to accommodate the resonator element and the oscillation circuit.
